(19) United States
(12) Patent Application Publication
(10) Pub. No.: US 2018/0018411 A1
(43) Pub. Date: Jan. 18, 2018

(54) METHOD AND APPARATUS OF BUILDING AGENT FOR TEST OF UNMANNED VEHICLE

(71) Applicant: BAIDU ONLINE NETWORK TECHNOLOGY (BEIJING) CO., LTD., Beijing (CN)

(72) Inventors: Tianlei Zhang, Beijing (CN); WenIi YANG, Beijing (CN); Yuchang PAN, Beijing (CN); Haowen SUN, Beijing (CN)

(73) Assignee: BAIDU ONLINE NETWORK TECHNOLOGY (BEIJING) CO., LTD., Beijing (CN)

(21) Appl. No.: 15/387,252

(22) Filed: Dec. 21, 2016

(30) Foreign Application Priority Data
Jul. 13, 2016 (CN) 201610552074.5

(51) Int. Cl. G06F 17/50; G05D 1/00

(52) U.S. Cl. CPC G06F 17/5009; G05D 1/0088

(57) ABSTRACT

The present invention discloses a method and apparatus for building an agent for test of an unmanned vehicle. The method comprises: obtaining feature information of an agent to be built; generating an agent according to the obtained feature information and verify whether a behavior of the agent is reasonable; considering the agent as a built agent if the behavior of the agent is determined reasonable. The solution of the present invention can be applied to quickly build an agent that meets needs of test of the unmanned vehicle.

The present application claims the priority of Chinese Patent Application No. 201610552074.5, filed on Jul. 13, 2016, with the title of “Method and apparatus of building agent for test of unmanned vehicle”.

### FIELD OF THE INVENTION

The present invention relates to unmanned vehicle test technologies, and particularly to a method and apparatus for building an agent for test of an unmanned vehicle.

### BACKGROUND OF THE INVENTION

During research and development of unmanned vehicles, a lot of real scenarios are needed to test correctness of algorithm.

However, it will be very dangerous and less efficient if all tests are performed in real traffic scenarios. Hence, it is necessary to use simulated traffic scenarios in place of real traffic scenarios to complete a lot of preliminary tests.

In a complicated traffic scenario, there are diverse agents which are in various forms and move freely by certain rules in the complicated traffic scenario.

The agents refer to entities that have an initiative moving capability, and may comprise pedestrians, bicycles, vehicles and the like.

Correspondingly, when a simulated traffic scenario is built, it is necessary to simulate a scenario map as well as various agents that might occur in the scenario. However, in the prior art there is not yet an effective method of building an agent for test of an unmanned vehicle.

### SUMMARY OF THE INVENTION

The present invention provides a method and apparatus for building an agent for test of an unmanned vehicle, which can quickly build an agent that meets needs of test of the unmanned vehicle.

Specific technical solutions are as follows:

A method for building an agent for test of an unmanned vehicle comprises:

obtaining feature information of an agent to be built;

generating an agent according to the feature information and verify whether the behavior of the agent is reasonable;

considering the agent as a built agent if the behavior of the agent is determined reasonable.

According to a preferred embodiment of the present invention, the feature information comprises attribute information and behavioral information.

According to a preferred embodiment of the present invention, the attribute information comprises a class to which it belongs to, length, width, height, an initial state;

the behavioral information comprises response behavior and a trigger condition of response behavior.

According to a preferred embodiment of the present invention, the obtaining feature information of an agent to be built comprises:

obtaining attribute information selected by the user from a pre-generated agent attribute information repository; and

obtaining behavioral information selected by the user from a pre-generated agent behavioral information repository.

According to a preferred embodiment of the present invention, the verifying whether the behavior of the agent is reasonable comprises:

uploading a map; and

playing back the behavior of the agent in the map.

According to a preferred embodiment of the present invention, the method further comprises: storing feature information of the agent in a predetermined format if the agent's behavior is determined reasonable.

An apparatus for building an agent for test of an unmanned vehicle, comprising:

an obtaining unit and a verifying unit;

the obtaining unit is configured to obtain feature information of an agent to be built, and send it to the verifying unit;

the verifying unit is configured to generate an agent according to the feature information, verify whether the behavior of the agent is reasonable, and consider the agent as a built agent if the behavior of the agent is determined reasonable.

According to a preferred embodiment of the present invention, the feature information comprises attribute information and behavioral information.

According to a preferred embodiment of the present invention, the attribute information comprises a class to which it belongs to, length, width, height, an initial state;

the behavioral information comprises response behavior and a trigger condition of response behavior.

According to a preferred embodiment of the present invention, the obtaining unit comprises: a first obtaining sub-unit and a second obtaining sub-unit;

The first obtaining sub-unit is configured to obtain attribute information selected by the user from a pre-generated agent attribute information repository, and send the user-selected attribute information to the verifying unit;

The second obtaining sub-unit is configured to obtain behavioral information selected by the user from a pre-generated agent behavioral information repository, and send the user-selected behavioral information to the verifying unit.

According to a preferred embodiment of the present invention, the verifying unit comprises: an uploading sub-unit and a verifying sub-unit;

The uploading sub-unit is configured to receive the feature information sent from the obtaining unit, send it to the verifying sub-unit, and upload the map;

The verifying sub-unit is configured to generate the agent according to the feature information, play back the behavior of the agent in the map to verify whether the behavior of the agent is reasonable, and consider the agent as a built agent if the behavior of the agent is determined reasonable.

According to a preferred embodiment of the present invention, the apparatus further comprises a storing unit;

The verifying sub-unit is further configured to send the feature information of the agent to the storing unit if the agent's behavior is determined reasonable;

The storing unit is configured to store the feature information of the agent in a predetermined format.

As can be seen from the above introduction, the solution of the present invention is employed to first obtain the feature information of the agent to be built, then generate the agent according to the obtained feature information and verify whether the generated agent's behavior is reasonable, and consider the generated agent as the built agent if the behavior is reasonable. In this way, the agent meeting the needs of test of the unmanned vehicle may be built quickly, and thereby a simulated traffic scenario is further built based on the built agent to replace the real traffic scenario to test the unmanned vehicle, thereby improving safety and efficiency of the test.

### BRIEF DESCRIPTION OF DRAWINGS

FIG. 1 is a flow chart of an embodiment of a method of building an agent for test of an unmanned vehicle according to the present invention.

FIG. 2 is a structural schematic view showing components of an embodiment of an apparatus for building an agent for test of an unmanned vehicle according to the present invention.

### DETAILED DESCRIPTION OF PREFERRED EMBODIMENTS

The solutions of the present invention will be further described in detail with reference with figures and embodiments to make technical solutions of the present invention clearer.

### Embodiment 1

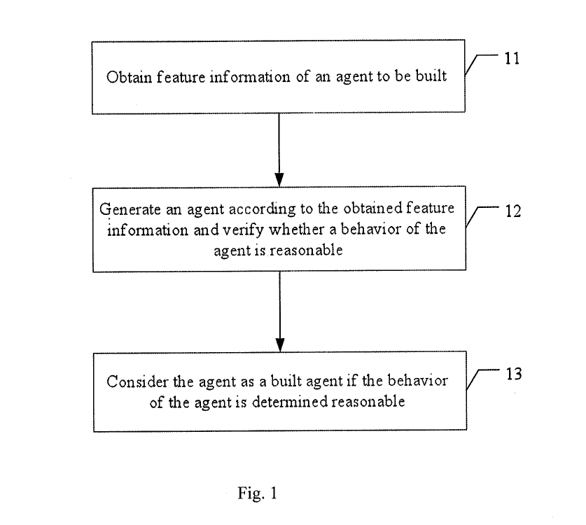

FIG. 1 is a flow chart of an embodiment of a method of building an agent for test of an unmanned vehicle according to the present invention. As shown in FIG. 1, the embodiment comprises the following specific implementation mode.

In step 11, feature information of an agent to be built is obtained.

The feature information of the agent to be built may comprise attribute information and behavioral information.

Wherein the attribute information refers to basic attribute information of the agent and may comprise a class to which it belongs to, length, width, height, an initial state and the like.

The initial state may further comprises: time of occurrence, an initial position, an initial speed, an initial direction and the like.

The behavioral information may comprise two portions, namely, response behavior and a trigger condition of response behavior.

The response behavior may comprise: acceleration, deceleration, stopping to wait, lane change and the like.

The trigger condition of the response behavior may comprise: arrival at a specific position, confrontation with traffic lights, confrontation with pedestrian crossing, confrontation with an agent ahead, and the like.

For example, the response behavior is deceleration, a corresponding trigger condition is confrontation with pedestrian crossing, and they both form a piece of behavioral information.

An agent attribute information repository and an agent behavioral information repository may be generated respectively in advance, the agent attribute information repository may store various attribute information having various agents that might occur in real traffic scenario, and the agent behavioral information repository may store various behavioral information having various agents that might occur in real traffic scenario.

Both the agent attribute information repository and the agent behavioral information repository may be established manually in advance, and information in the agent attribute information repository and the agent behavioral information repository may be obtained by investigating agents in the real traffic scenario and performing manual experience.

Furthermore, information in the agent attribute information repository and the agent behavioral information repository may be updated at any time according to actual needs, and the update may comprise: increasing information, deleting existing information, modifying existing information and the like.

It is feasible to display to the user a visual interaction type agent editing interface which may comprise an agent attribute information management area and an agent behavioral information management area.

The user may input, in an input box displayed in the agent attribute information management area, a class to which the agent to be built belongs, for example, truck. Various possible length/width/height values, various possible initial speeds and various possible initial directions corresponding to the truck may be displayed to be user, and the user may select desired attribute information (attribute value) respectively therefrom, or the user may also initiatively set other values other than the displayed attribute values.

Similarly, the user may input, in an input box displayed in the agent behavioral information management area, a class to which the agent to be built belongs, for example, truck, and correspondingly may display various behavioral information corresponding to the truck to the user, and the user may select desired behavioral information therefrom.

It needs to be appreciated that the above-mentioned manner of obtaining the attribute information and behavioral information of the agent to be built is only for exemplary illustration and not intended to limit the technical solution of the present invention. In addition to this manner, any other manners that can be envisioned by those skilled in the art may also be used, and which manner is specifically employed may depend on actual needs.

In step 12, an agent is generated according to the obtained feature information, and whether the behavior of the agent is reasonable is verified.

After the attribution information and behavioral information of the agent is obtained, an agent may be generated in a current manner, and whether the behavior of the agent is reasonable is verified.

A specific verifying manner is: uploading a pre-generated map, and playing back the behavior of the agent in the map.

The agent editing interface may comprise an agent display area which may upload the map to the area and play back the behavior of the agent in the map.

The map is a high-precision map. As compared with an ordinary map, the high-precision map contains richer content, e.g., it may comprise lane lines, lane boundary, zebra lines, stop line, traffic lights, traffic signs, precise positions of lane lines, lane speed limit and the like.

Playing back the behavior of the agent in the map refers to enabling the agent to run on the high-precision map according to the initial state and behavioral information of the agent.

If the agent is a pedestrian, playing back the pedestrian's behavior refers to enabling the pedestrian to walk in the high-precision map according to the attribute information and behavioral information obtained from step 11.

How to play back the behavior of the agent is of the prior art.

In step 13, if the behavior of the agent is determined reasonable, the agent is considered as a built agent.

The user may observe the behavior playback procedure of the agent in real time.

If the agent has been running according to set behavioral information and it decelerates when it comes to a pedestrian crossing occurring in the map, the agent's behavior may be considered reasonable, and thereby the agent is regarded as the built agent.

Regarding the built agent, its feature information may be stored in a predetermined format, i.e., the feature information obtained in step 11 is stored in a predetermined format, and subsequently the stored information may be directly invoked when necessary.

The predetermined format may be an Extensible Markup Language (XML) format.

A plurality of agents in different classes may be generated respectively in the above manner. As such, when a simulated traffic scenario needs to be built, after the scenario map is built, the desired agent may be added to the scenario map to thereby obtain the simulated traffic scenario so that the simulated traffic scenario may be used to test the unmanned vehicle.

The method embodiment is introduced above. The solution of the present invention will be further described below by describing an apparatus embodiment.

### Embodiment 2

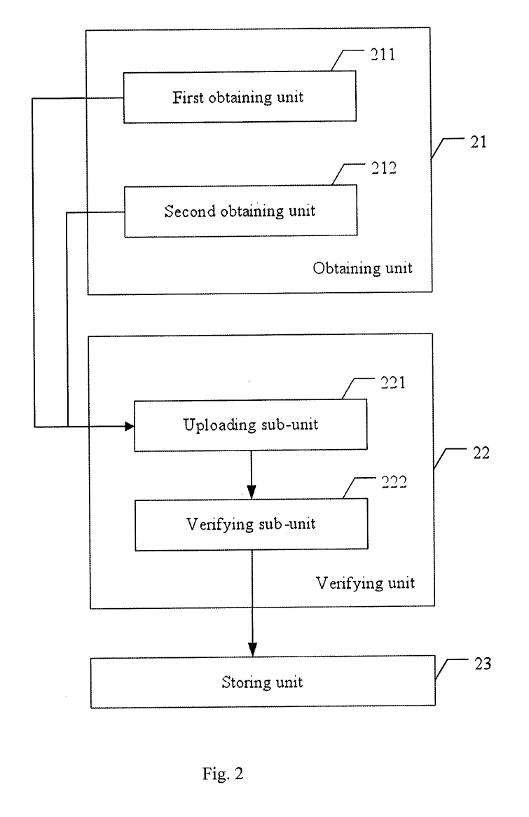

FIG. 2 is a structural schematic view showing components of an embodiment of an apparatus for building an agent for test of an unmanned vehicle according to the present invention. As shown in FIG. 2, the apparatus comprises an obtaining unit 21 and a verifying unit 22.

The obtaining unit 21 is configured to obtain feature information of an agent to be built, and send it to the verifying unit 22;

The verifying unit 22 is configured to generate an agent according to the obtained feature information, verify whether the behavior of the agent is reasonable, and consider the agent as a built agent.

The feature information of the agent to be built may comprise attribute information and behavioral information.

Wherein the attribute information refers to basic attribute information of the agent and may comprise a class to which it belongs to, length, width, height, an initial state and the like.

The initial state may further comprises: time of occurrence, an initial position, an initial speed, an initial direction and the like.

The behavioral information may comprise two portions, namely, response behavior and a trigger condition of the response behavior.

The response behavior may comprise: acceleration, deceleration, stopping to wait, lane change and the like.

The trigger condition of the response behavior may comprise: arrival at a specific position, confrontation with traffic lights, confrontation with pedestrian crossing, confrontation with an agent ahead, and the like.

For example, the response behavior is deceleration, a corresponding trigger condition is confrontation with pedestrian crossing, and they both form a piece of behavioral information.

As shown in FIG. 2, the obtaining unit 21 may specifically comprise: a first obtaining sub-unit 211 and a second obtaining sub-unit 212.

The first obtaining sub-unit 211 is configured to obtain attribute information selected by the user from a pre-generated agent attribute information repository, and send the user-selected attribute information to the verifying unit 22; The second obtaining sub-unit 212 is configured to obtain behavioral information selected by the user from a pre-generated agent behavioral information repository, and send the user-selected behavioral information to the verifying unit 22.

The agent attribute information repository and the agent behavioral information repository may be generated respectively in advance, the agent attribute information repository may store various attribute information having various agents that might occur in real traffic scenario, and the agent behavioral information repository may store various behavioral information having various agents that might occur in real traffic scenario.

Both the agent attribute information repository and the agent behavioral information repository may be established manually in advance, and information in the agent attribute information repository and the agent behavioral information repository may be obtained by investigating agents in the real traffic scenario and performing manual experience.

Furthermore, information in the agent attribute information repository and the agent behavioral information repository may be updated at any time according to actual needs, and the update may comprise: increasing information, deleting existing information, modifying existing information and the like.

As shown in FIG. 2, the verifying unit 22 may specifically comprise: an uploading sub-unit 221 and a verifying sub-unit 222.

The uploading sub-unit 221 is configured to receive the feature information sent from the obtaining unit 21, send it to the verifying sub-unit 222, and upload the map;

The verifying sub-unit 222 is configured to generate the agent according to the received feature information, play back the behavior of the agent in the map to verify whether the behavior of the agent is reasonable, and consider the agent as a built agent if the behavior of the agent is determined reasonable.

The map is a high-precision map. As compared with an ordinary map, the high-precision map contains richer content, e.g., it may comprise lane lines, lane boundary, zebra lines, stop line, traffic lights, traffic signs, precise positions of lane lines, lane speed limit and the like.

Playing back the behavior of the agent in the map refers to enabling the agent to run on the high-precision map according to the initial state and behavioral information of the agent.

The user may observe the behavior playback procedure of the agent in real time. If the agent has been running according to set behavioral information and it decelerates when it comes to a pedestrian crossing occurring in the map, the agent's behavior may be considered reasonable, and correspondingly, if the verifying sub-unit 222 receives a successful verification instruction from the user, the agent is regarded as the built agent.

As shown in FIG. 2, the apparatus shown in FIG. 2 may further comprise a storing unit 23.

The verifying sub-unit 222 may be further configured to send the feature information of the agent to the storing unit 23 if the agent's behavior is determined reasonable;

The storing unit 23 is configured to store the received feature information of the agent in a predetermined format.

Regarding the feature information of the agent stored in a predetermined format, it may be directly invoked subsequently when necessary.

The predetermined format may be an Extensible Markup Language (XML) format.

To sum up, the solution of the present invention is employed to first obtain the feature information of the agent to be built, then generate the agent according to the obtained feature information and verify whether the generated agent's behavior is reasonable, and consider the generated agent as the built agent if the behavior is reasonable. In this way, the agent meeting the needs of test of the unmanned vehicle may be built quickly, and thereby a simulated traffic scenario is further built based on the built agent to replace the real traffic scenario to test the unmanned vehicle, thereby improving safety and efficiency of the test; furthermore, the solution of the present invention may be implemented simply and conveniently and therefore easy to spread and popularize.

In the embodiments provided by the present invention, it should be understood that the revealed apparatus and method can be implemented in other ways. For example, the apparatus embodiment described above is only exemplary, e.g., the division of the units is merely logical function division, and, in reality, they can be divided in other ways upon actual implementation.

The units described as separate parts may be or may not be physically separated, the parts shown as units may be or may not be physical units, i.e., they can be located in one place, or distributed in a plurality of network units. One can select some or all the units therefrom according to actual needs to achieve the solution of the present embodiment.

Further, in the embodiments of the present invention, functional units can be integrated in one processing unit, or they can be separate physical presences; or two or more units can be integrated in one unit. The integrated unit described above can be realized in the form of hardware, or they can be realized with hardware and software functional units.

The aforementioned integrated unit implemented in the form of software function units may be stored in a computer readable storage medium. The aforementioned software function units are stored in a storage medium, including several instructions to instruct a computer device (a personal computer, server, or network equipment, etc.) or processor to perform some steps of the method described in the various embodiments of the present invention. The aforementioned storage medium includes various media that may store program codes, such as U disk, removable hard disk, read-only memory (ROM), a random access memory (RAM), magnetic disk, or an optical disk.

The foregoing is only preferred embodiments of the present invention, not intended to limit the invention. Any modifications, equivalent replacements, improvements and the like made within the spirit and principles of the present invention, should all be included in the present invention within the scope of protection.

What is claimed is:

1. A method for building an agent for test of an unmanned vehicle, wherein the method comprises:
obtaining feature information of an agent to be built;
generating an agent according to the feature information and verifying whether a behavior of the agent is reasonable;
considering the agent as a built agent if the behavior of the agent is determined reasonable.

2. The method according to claim 1, wherein the feature information comprises attribute information and behavioral information.

3. The method according to claim 2, wherein
the attribute information comprises a class to which it belongs to, length, width, height, and an initial state;
the behavioral information comprises response behavior and a trigger condition of response behavior.

4. The method according to claim 2, wherein
the obtaining feature information of an agent to be built comprises:
obtaining attribute information selected by the user from a pre-generated agent attribute information repository; and
obtaining behavioral information selected by the user from a pre-generated agent behavioral information repository.

5. The method according to claim 1, wherein
the verifying whether the behavior of the agent is reasonable comprises:
uploading a map; and
playing back the behavior of the agent in the map.

6. The method according to claim 1, wherein
the method further comprises:
storing feature information of the agent in a predetermined format if the agent's behavior is determined reasonable.

7. A nonvolatile computer storage medium, stored with one or more programs, which, when executed by an apparatus, make the apparatus to execute the following operation:
obtaining feature information of an agent to be built;
generating an agent according to the feature information and verifying whether a behavior of the agent is reasonable;
considering the agent as a built agent if the behavior of the agent is determined reasonable.

8. The nonvolatile computer storage medium according to claim 7, wherein the feature information comprises attribute information and behavioral information.

9. The nonvolatile computer storage medium according to claim 8, wherein
the attribute information comprises a class to which it belongs to, length, width, height, and an initial state;
the behavioral information comprises response behavior and a trigger condition of response behavior.

10. The nonvolatile computer storage medium according to claim 8, wherein
the operation of obtaining feature information of an agent to be built comprises:
obtaining attribute information selected by the user from a pre-generated agent attribute information repository; and
obtaining behavioral information selected by the user from a pre-generated agent behavioral information repository.

11. The nonvolatile computer storage medium according to claim 7, wherein
the operation of verifying whether the behavior of the agent is reasonable comprises:
uploading a map; and
playing back the behavior of the agent in the map.

12. The nonvolatile computer storage medium according to claim 7, wherein
the operation further comprises:
storing feature information of the agent in a predetermined format if the agent's behavior is determined reasonable.

13. An apparatus, comprising:
one or more processors;
a memory;
one or more programs, which are stored in the memory, and execute the following operation, when executed by the one or more processors:
obtaining feature information of an agent to be built;
generating an agent according to the feature information and verifying whether a behavior of the agent is reasonable;
considering the agent as a built agent if the behavior of the agent is determined reasonable.

14. The apparatus according to claim 13, wherein the feature information comprises attribute information and behavioral information.

15. The apparatus according to claim 14, wherein
the attribute information comprises a class to which it belongs to, length, width, height, and an initial state;
the behavioral information comprises response behavior and a trigger condition of response behavior.

16. The apparatus according to claim 14, wherein
the operation of obtaining feature information of an agent to be built comprises:
obtaining attribute information selected by the user from a pre-generated agent attribute information repository; and
obtaining behavioral information selected by the user from a pre-generated agent behavioral information repository.

17. The apparatus according to claim 13, wherein
the operation of verifying whether the behavior of the agent is reasonable comprises:
uploading a map; and
playing back the behavior of the agent in the map.

18. The apparatus according to claim 13, wherein
the operation further comprises:
storing feature information of the agent in a predetermined format if the agent's behavior is determined reasonable.
